(19) United States
(12) Patent Application Publication
(10) Pub. No.: US 2004/0110329 A1
(43) Pub. Date: Jun. 10, 2004

(54) Method and apparatus for fabricating thin film transistor including crystalline active layer

(75) Inventors: Seung Ki Joo, Seongnam-si (KR); Seok-Woon Lee, Incheon (KR)

Correspondence Address: BAKER BOTTS L.L.P., 2001 ROSS AVENUE, SUITE 600, DALLAS, TX, 75201-2980, US

(73) Assignee: Seung Ki Joo

(21) Appl. No.: 10/718,141

(22) Filed: Nov. 20, 2003

Related U.S. Application Data
(62) Division of application No. 10/055,693, filed on Jan. 22, 2002, now abandoned.

(30) Foreign Application Priority Data
Jan. 20, 2001 (KR) 2001-3464

(51) Int. Cl. H01L 21/00; H01L 21/84

(52) U.S. Cl. 438/166

(57) ABSTRACT

The present invention relates to a method and apparatus for fabricating a thin film transistor including a crystalline silicon active layer. According to the method of the present invention, there are advantages in that processing time and production costs can be reduced since a series of processes of fabricating the thin film transistor, such as deposition of source metal, thermal annealing for crystallization, and deposition of an insulating layer or a wiring metal layer, can be consecutively performed in one apparatus.

### CROSS REFERENCE TO RELATED APPLICATIONS

This application is a divisional of U.S. application Ser. No. 10/055,693, filed Jan. 22, 2002, by Seung Ki Joo and Seok-Woon Lee entitled “METHOD AND APPARATUS FOR FABRICATING THIN FILM TRANSISTOR INCLUDING CRYSTALLINE ACTIVE LAYER.”

### TECHNICAL FIELD OF THE INVENTION

The present invention relates to a method and apparatus for fabricating a thin film transistor (TFT) including a crystalline silicon active layer.

### DESCRIPTION OF THE PRIOR ART

A thin film transistor for use in a display device such as a liquid crystal display (LCD) and an organic light-emitting diode (OLED) is usually fabricated in such a manner that silicon is deposited on a transparent substrate made of glass, quartz, or the like; gates and gate electrodes are formed thereon; dopants are implanted into source and drain regions and are activated in a process of annealing; and then an insulating layer is formed thereon. An active layer for constituting the source and drain regions, and a channel of the thin film transistor is generally formed by depositing a silicon layer onto the transparent substrate made of glass using a chemical vapor deposition (CVD) method. However, the silicon layer deposited directly onto the substrate by using a method such as CVD is an amorphous silicon film having low electron mobility. As the display device employing the thin film transistors requires a fast operating speed and is miniaturized, the degree of integration of driving integrated circuits (ICs) is increased and an aperture ratio of a pixel area is decreased. Thus, it is necessary to simultaneously form the driving circuits and the pixel TFTs and to increase the pixel aperture ratio by improving the electron mobility of the silicon film. To this end, a technique for forming polycrystalline polysilicon having high electron mobility by means of crystallization of the amorphous silicon layer through the annealing thereof has been used.

A thin film transistor employing a crystalline silicon film is a well-known device, and is fabricated by forming a thin film of semiconductor such as silicon on a semiconductor substrate with an insulating layer formed thereon or directly on an insulation substrate. The thin film transistor is used for various integrated circuits, and particularly, for switching devices formed at the respective pixels of the liquid crystal display, driving circuits formed in peripheral circuit regions, or the like.

In order to obtain a polycrystalline silicon thin film for use in such a device, it is well known that a deposited amorphous silicon thin film should be thermal annealed at a temperature of about 600° C. or higher. Since the polycrystalline silicon thin film transistor as a device for driving the liquid crystal display should be formed on a glass substrate, however, the thermal annealing temperature should be a relatively low temperature equal to or less than about 600° C., i.e. a deformation temperature of the glass substrate. Therefore, studies for solving the problem have progressed in the following two directions.

First, there is a crystallization method in which a portion of the amorphous silicon thin film is fused and crystallized by irradiating laser beam thereon. According to this method, the crystallization of the silicon thin film can be made without deformation of the substrate, since only a portion of the silicon thin film is heated without greatly raising the temperature of the substrate. However, there are problems such as low uniformity of the crystallization, high production costs, and low production yield.

Second, there is a method conventionally called metal induced lateral crystallization (MILC), in which the crystallization temperature is lowered below about 500° C. by depositing a metal thin film onto the amorphous silicon thin film. In this method, the amorphous silicon is crystallized by subjecting it to thermal annealing in a furnace after depositing the metal thin film onto the amorphous silicon thin film. According to the method, the problems of laser annealing method such as the low uniformity of the crystallization and the low production yield can be avoided and solved to a great degree. However, there is still a problem in that thermal annealing should be performed at a temperature of about 500° C. for several hours if the method is to be applied to an actual process, and thus, which significantly extends the processing time of the MILC crystallization.

The present invention relates to a method of crystallizing the amorphous silicon constituting an active layer of the thin film transistor by using the MILC method, and to an apparatus for use in the method. Hereinafter, before description of the constitution of the present invention, a conventional method of fabricating a thin film transistor including a crystalline silicon active layer by using the MILC method will be explained with reference to FIGS. 1a to 1g.

FIG. 1A is a sectional view showing a state where an amorphous silicon layer 11 constituting an active layer of a thin film transistor is formed on an insulating substrate 10 and then patterned. The substrate 10 is comprised of transparent insulating materials such as alkali-free glass, quartz, or silicon oxide. Alternatively, a lower insulating layer (not shown) for preventing diffusion of contaminants from the substrate into the active layer may be formed on the substrate. The lower insulating layer can be formed by performing deposition of silicon oxide (SiO₂), silicon nitride (SiNₓ), silicon oxynitride (SiOₓN_{y}) or the composite material thereof at temperature of about 600° C. or lower and to thickness of 300 to 10,000 Å, more preferably 500 to 3,000 Å, using a vapor deposition method such as plasma-enhanced chemical vapor deposition (PECVD), low-pressure chemical vapor deposition (LPCVD), atmospheric pressure chemical vapor deposition (APCVD), electron cyclotron resonance CVD (ECR-CVD), etc. The active layer 11 is formed by performing deposition of amorphous silicon to thickness of 100 to 3,000 Å, more preferably 500 to 1,000 Å, using PECVD, LPCVD or sputtering. The active layer comprises a source region, a drain region, a channel region, and an optional region for device/electrode to be formed later. The active layer formed on the substrate is patterned to meet the specification of a TFT to be fabricated. The active layer is patterned through dry etching using plasma of an etching gas and employing patterns made by photolithography as a mask.

FIG. 1B is a sectional view of a structure in which a gate insulating film 12 and a gate electrode 13 are formed on the substrate 10 and the patterned active layer 11. The gate insulating film 12 is formed by performing deposition of silicon oxide (SiO₂), silicon nitride (SiNₓ), silicon oxynitride (SiOₓN_{y}) or the composite material thereof to thickness of 300 to 3,000 Å, more preferably 500 to 1,000 Å, using a vapor deposition method such as PECVD, LPCVD, APCVD, and ECR-CVD. The gate electrode 13 is constructed in such a manner that a gate electrode layer is formed by depositing conductive material such as metallic material or doped polysilicon onto the gate insulating film to thickness of 1,000 to 8,000 Å, more preferably 2,000 to 4,000 Å, using the method such as sputtering, evaporation, PECVD, LPCVD, APCVD, and ECR-CVD, and that the gate insulating film and the gate electrode layer are then simultaneously patterned. The gate electrode is patterned through wet or dry etching generally employing a photolithography pattern as a mask.

FIG. 1C is a view showing a process of doping the source region 11S and the drain region 11D of the active layer by using the gate electrode as a mask. In a case where an N-MOS TFT is fabricated, dopants such as PH₃, P, As, etc. are doped at a dose of about 1.0×10¹¹ to 1.0×10^{22/} cm³ (preferably, 1.0×10¹⁵ to 1.0×10²¹/cm³) with energy of about 10 to 200 keV (preferably, 30 to 100 keV) using ion shower doping or ion implantation. Further, in a case where a P-MOS TFT is fabricated, dopants such as B₂H₆, B, BH₃, etc. are doped at a dose of about 1.0×10¹¹ to 1.0×10^{22/}cm³ (preferably, 1.0×10¹⁴ to 1.0×10²¹/cm³) with energy of about 20 to 70 keV. For example, in a case where a junction portion having a lightly doped region or an offset region is formed in the drain region or where a CMOS is formed, additional doping processes using additional masks are required.

FIG. 1D is a sectional view showing a structure in which contact holes are formed in such a manner that after the active layer is doped, an insulating layer 14 as a contact insulating layer is formed on the gate insulating film 12 and the gate electrode 13 and then is patterned. The insulating layer is formed by performing deposition of silicon oxide, silicon nitride, silicon oxynitride or the composite material thereof to thickness of 1,000 to 15,000 Å, more preferably 3,000 to 7,000 Å, using a deposition method such as PECVD, LPCVD, APCVD, ECR-CVD, and sputtering. The insulating layer is wet or dry etched generally using a photolithography pattern as a mask, so that the contact holes 15 through which the contact electrodes are connected to the source and drain regions of the active layer are formed.

FIG. 1E is a sectional view showing a state where metal layer 16 for inducing metal induced crystallization (MIC) or MILC of the amorphous silicon constituting the active layer is applied to the source region 11S and the drain region 11D which are exposed through the contact holes, respectively. As for metal for inducing the MIC or MILC phenomenon of the amorphous silicon, Ni or Pd is preferably used, and Ti, Ag, Au, Al, Sn, Sb, Cu, Co, Cr, Mo, Tr, Ru, Rh, Cd, Pt and the like may also be used. The metal such as Ni or Pd for inducing MILC can be applied to the active layer by using sputtering, evaporation, PECVD, or ion implantation method. However, sputtering method is most frequently used. The thickness of the deposited metal layer may be arbitrarily selected within a range required for inducing the MIC or MILC of the active layer, and is approximately within a range of 1-10,000 Å, and preferably 10-200 Å. The metal layer which has been applied to the portions other than the interior of the contact holes can be removed simultaneously when the photoresist and the like used as a mask for forming

the contact holes in the insulating layer is removed by using a method such as lift-off and the like.

FIG. 1F shows a process in which dopants implanted into the source and drain regions of the active region are activated and the crystallization of the active layer is simultaneously induced, by forming a source metal layer 16 within the contact holes and then performing the thermal annealing thereof. This process is performed by employing a rapid thermal annealing (RTA) method in which the materials are heated during a short period of time within several minutes at a temperature of about 700 or 800° C. using a tungsten-halogen or Xe arc heating lamp, or an ECL method in which the materials are heated during a very short period of time using an eximer laser. Preferably, the thermal annealing is performed in a furnace at a temperature of 400-600° C. during 0.1-50 hours, more preferably during 0.5-20 hours. During the thermal annealing, the source and drain regions 17 to which the MIC source metal has been applied through the contact holes are crystallization by the MIC phenomenon. The source and drain regions to which the MIC source metal has been not applied, and the channel region 18 are crystallized by the MILC propagating from the portions to which the MIC source metal has been applied. An arrow shown in FIG. 1F indicates the propagation direction of the MILC. The MILC phenomenon that propagates from the portions to which the source metal has been applied is progressed from both of the contact areas, and thus, the entire regions of the active layer are eventually crystallized.

FIG. 1G is a sectional view showing a state where contact electrodes which connect the source and drain regions of the active layer with external circuits through the contact holes are formed after crystallizing the active layer through the thermal annealing. The process of forming the contact electrodes comprises the processes of depositing a conductive material such as metal and doped polysilicon on the entire insulating layer to a thickness of 500-10,000 Å, more preferably 2,000-6,000 Å by using a method such as sputtering, evaporation, or CVD, and then patterning the conductive material in a desired shape by using dry or wet etching. After patterning the contact electrodes, additional thermal annealing may be performed by using a high-temperature furnace, a laser or a high-temperature lamp so as to improve the crystallization quality of the active layer.

A flowchart of FIG. 2 summarizes a sequence of the processes as above described with reference to FIGS. 1A to 1G. However, when the sequence of the processes as shown in FIGS. 1A to 1G and 2 are used, there are some problems as follows. Vacuum equipment such as a sputtering apparatus or vapor deposition apparatus must be used in the process of depositing the MIC source metal shown in FIG. 1E. Furthermore, in order to thermal-anneal the substrate as shown in FIG. 1F after depositing the MIC source metal, it is inevitable to release the vacuum state of the vacuum used for depositing the metal, take out the substrate from the vacuum equipment, and load it into the annealing equipment. At this time, in order to prevent a thermal shock to the substrate, the substrate must be loaded into the furnace after lowering the temperature of the furnace to appropriate temperature ( 100° C.). Therefore, it takes several hours to raise the temperature of the furnace up to an appropriate thermal annealing temperature about 500°. Furthermore, for the same reason, the substrate must be taken out from the furnace after the thermal annealing is completed and then the temperature of the furnace is lowered to an appropriate temperature. Therefore, the period of time during which the substrate is taken out from the furnace after loading the substrate into the furnace and completing the thermal annealing becomes significantly longer than that required for actually performing the thermal annealing. In order to deposit the contact electrodes and the wiring metal after the thermal annealing, the vacuum equipment such as sputtering apparatus or vapor depositing apparatus must be used again. In order to perform the deposition after loading the substrate into the vacuum equipment again, the pressure in the vacuum equipment must be lowered to an appropriate level, and thus, takes much times to do so.

### SUMMARY OF THE INVENTION

An object of the present invention is to provide a method of fabricating a thin film transistor and an apparatus for use in the method for solving above problems such as the complexity and the excessive delay of the process.

Another object of the present invention is to provide a method and apparatus for reducing the time and costs needed to fabricate of a thin film transistor by consecutively performing the deposition of MIC source metal, the thermal annealing for crystallizing amorphous silicon and activating the doped impurities, and the deposition of wiring metal layer within one equipment maintaining its vacuum state.

A further object of the present invention is to provide a method and apparatus capable of consecutively performing the deposition of MIC source metal and the thermal annealing process for crystallizing amorphous silicon and activating the doped impurities together with a process of forming a contact insulating layer or with a process of forming a gate insulating film/a gate electrode within one equipment maintaining its vacuum state.

A further object of the present invention is to provide a method and apparatus which are capable of simultaneously conducting the processes of MIC source metal deposition and thermal annealing for crystallizing amorphous silicon and for activating impurities; the processes of thermal annealing and the deposition of wiring metal layer; or the processes of the thermal annealing and the formation of an insulating layer used for forming contact holes, according to the sequence of the TFT fabrication processes adopted.

### BRIEF DESCRIPTION OF THE DRAWINGS

The above objects and features of the present invention will become apparent from the following description of preferred embodiments given in connection with the accompanying drawings, in which:

FIGS. 1A to 1G are sectional views showing a conventional fabricating process of a thin film transistor;

FIG. 2 is a flowchart of the fabricating process shown in FIGS. 1A to 1G;

FIGS. 3A to 3E are sectional views showing a fabricating process of a thin film transistor according to a preferred embodiment of the present invention;

FIG. 4 is a flowchart of the fabricating process shown in FIGS. 3A to 3E;

FIG. 5 is a schematic view showing the constitution of an apparatus for fabricating the thin film transistor according to a preferred embodiment of the present invention;

FIGS. 6A to 6D are sectional views showing a fabricating process of a thin film transistor according to another preferred embodiment of the present invention;

FIG. 7 is a flowchart of the fabricating process shown in FIGS. 6A to 6D;

FIGS. 8A to 8C are sectional views showing a fabricating process of a thin film transistor according to a further preferred embodiment of the present invention;

FIG. 9 is a flowchart of the fabricating process shown in FIGS. 8A to 8C;

FIGS. 10A to 10C are sectional views showing a fabricating process of a thin film transistor according to a further preferred embodiment of the present invention; and

FIG. 11 is a flowchart of the fabricating process shown in FIGS. 10A to 10C.

### DETAILED DESCRIPTION OF THE INVENTION

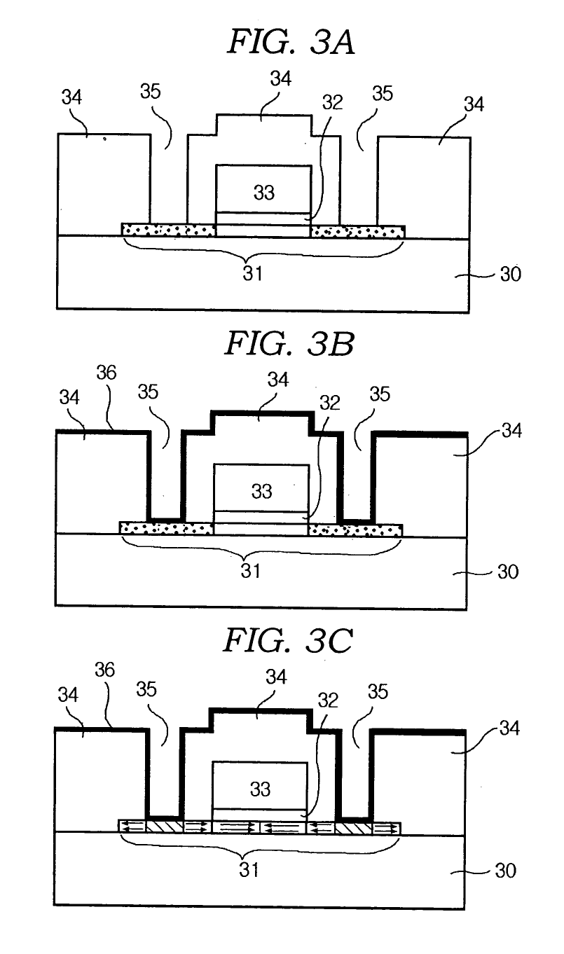

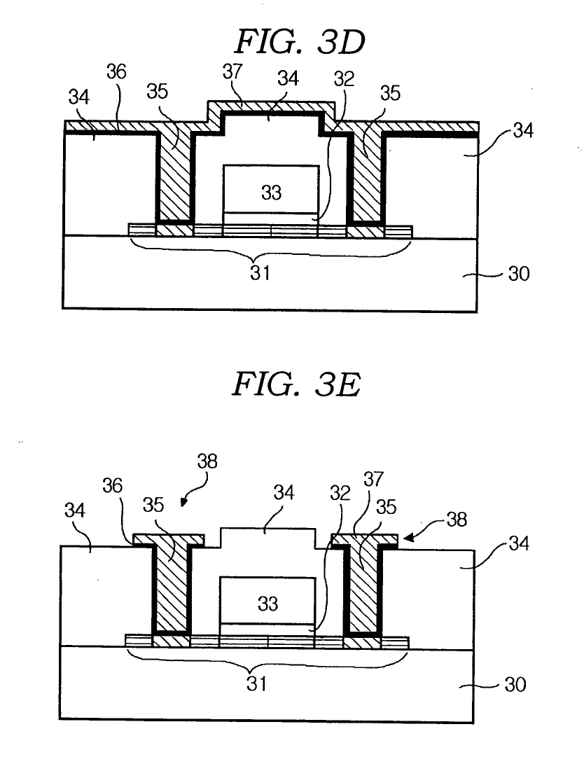

FIGS. 3A to 3E show a process of fabricating a thin film transistor including a crystalline silicon active layer by crystallizing amorphous silicon according to an embodiment of the present invention.

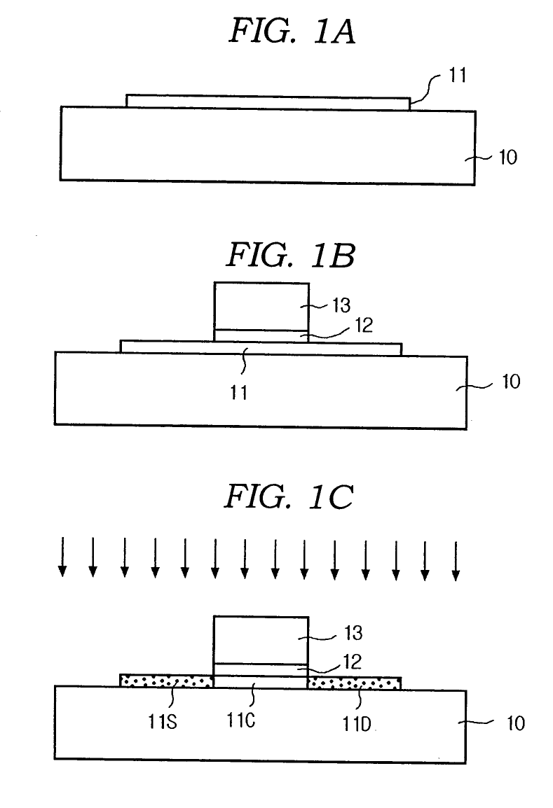

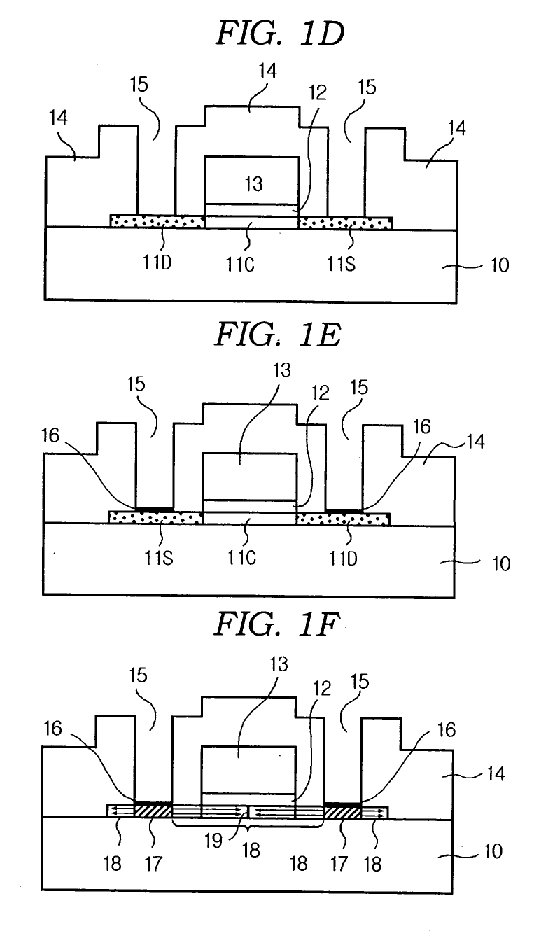

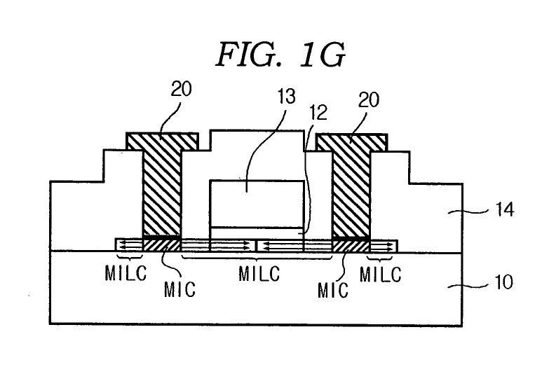

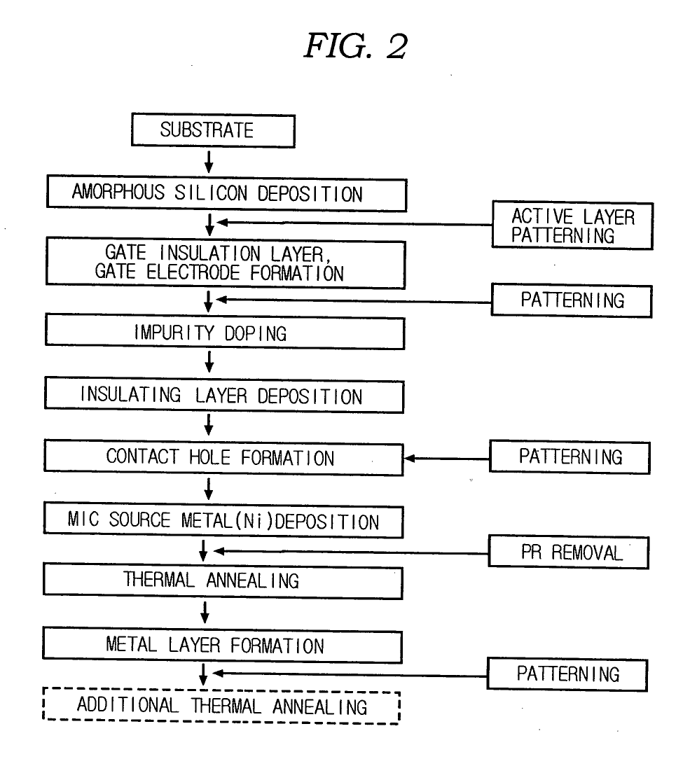

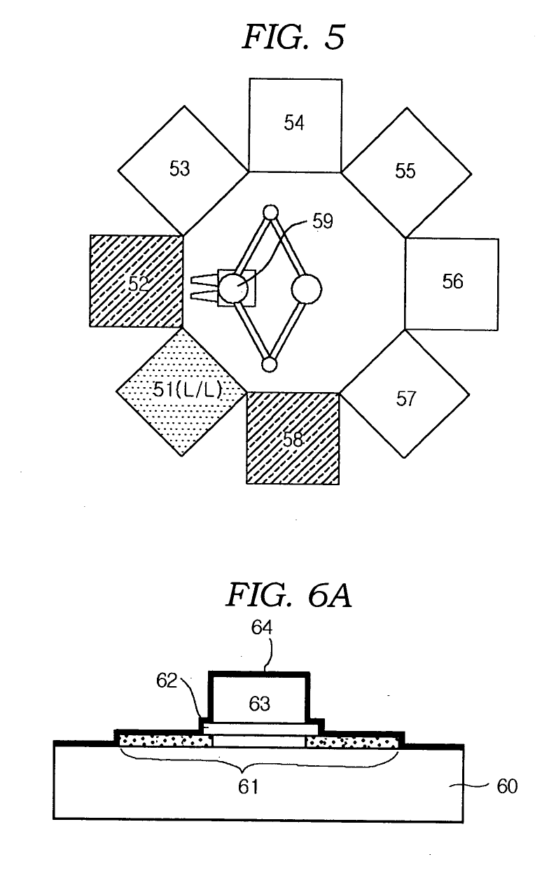

In the present embodiment, an amorphous silicon active layer 31 is firstly deposited onto a substrate 30 by using the same method as described with reference to FIGS. 1A to 19, a gate insulating film 32 and a gate electrode 33 are formed, impurities are implanted and an insulating layer 34 is then deposited, contact holes 35 are formed in the insulating layer 34, and photoresist used for forming the contact holes is removed, so that the structure shown in FIGS. 3A is obtained. After the contact holes 35 are formed, a process of depositing MIC source metal, a thermal annealing process, and a process of depositing a wiring metal layer are collectively performed by using an apparatus to be described later with reference to FIG. 5. In the process described with reference to FIGS. 1A to 1G and 2, the MIC source metal is deposited without removing a mask such as the photoresist used for forming the contact holes, and the MIC source metal which is applied to the portions other than the active layer regions exposed through the contact holes is removed when removing the photoresist using a lift-off method and the like (See FIG. 1E). However, in the present embodiment, after forming the contact holes 35, the photoresist used as the mask is removed before depositing the MIC source metal. Then, the MIC source metal 36 is deposited on the entire insulating layer by using the same method as described with reference to FIG. 1E, and therefore, the structure shown in FIG. 3B is obtained. In these processes, the MIC source metal is deposited on an external surface of the insulating layer 34 and inside the contact holes 35, and therefore, the MIC source metal 36 is applied to a surface of the active layer 31, which is exposed through the contact holes.

Then the structure shown in FIG. 3b is subjected to thermal annealing under vacuum which has been used for the metal deposition and under the same condition as described in connection with FIG. 1F by using an apparatus to be described later with reference to FIG. 5. During the thermal annealing, the crystallization of the active layer 31 is progressed from the portions where the MIC source metal 36 is applied through the contact holes 35, as shown in FIG. 3C. At this time, since the MIC source metal which has been deposited on the external surface of the insulating layer 34 or inner side walls of the contact holes does not make contact with the amorphous silicon forming the active layer, it has no effect on the crystallization of the active layer. If the crystallization of the active layer is completed, a wiring metal layer 37 which forms the contact electrodes and conductive lines of the thin film transistor is deposited on the MIC source metal 36 layer under vacuum in the apparatus as shown in FIG. 5, and thus, the structure shown in FIG. 3D is obtained. In the embodiment of the present invention, the wiring metal layer 37 may also be formed of the same kind of metal as the MIC source metal 36. Furthermore, the MIC source metal layer and the wiring metal layer may be formed integrally with each other at a time and thermal annealed so as to use the MIC source metal layer as the wiring metal layer, if necessary. Since the MIC source metal used in the present invention has good conductivity, if the MIC source metal layer is interposed between the contact electrodes and the active layer, silicide having good conductivity is formed on the active layer of the transistor. Accordingly, the additional advantage of lowering contact resistance is obtained.

After the wiring metal layer is formed, a thin film transistor is completed by patterning the wiring metal layer 37 in a desired shape of the wiring elements such as the contact electrodes 38 using etching or the like as shown in FIG. 3E. After or before patterning the wiring elements, additional thermal annealing of the substrate may be performed as described above.

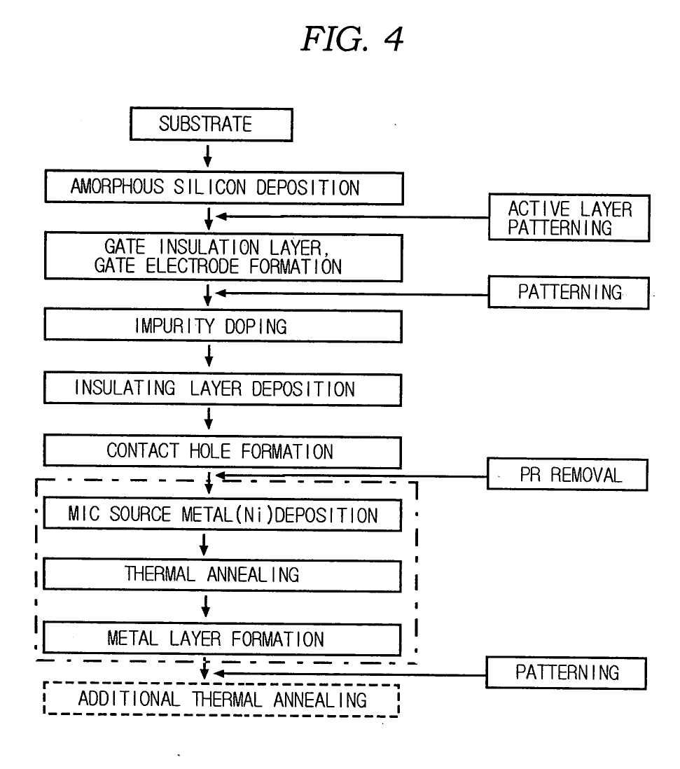

FIG. 4 shows a flowchart for explaining the aforementioned processes. Using the method of the present embodiment, a series of the processes (the processes enclosed by the dotted line) from the process of depositing the MIC source metal to the process of depositing the wiring metal layer may be performed without releasing the vacuum state because the processes are not intervened by a process of forming or patterning photoresist. Thus, the series of the processes are consecutively performed within one equipment maintaining the vacuum state. Therefore, with the method of the present invention, the process of depositing the source metal, the thermal annealing process, and the process of depositing the wiring metal layer are collectively performed within the one equipment without stopping the processes.

Consequently, there is an advantage of greatly reducing the time and cost needed for fabricating the thin film transistor.

FIG. 5 shows the schematic constitution of one example of an apparatus used for performing the method according to the present invention. In order to perform the collective processes as described with reference to FIGS. 3A to 3E and 4, the apparatus shown in FIG. 5 has a cluster type structure comprising a load lock system 51, a chamber 52 for depositing the MIC source metal, a high-temperature chambers 53 to 57 for performing the thermal annealing, a chamber 58 for depositing the wiring metal, and a robot arm 59 for transferring the substrate. Here, the number or arrangement of the respective chambers may be properly changed in accordance with the process condition so that the productivity can be maximized. The interior of the apparatus is maintained Under vacuum while the substrate is loaded into the apparatus through the load lock system 51, the processing of the substrate is completed, and then the substrate is taken out outside the apparatus through the load lock system. The internal pressure of the apparatus shown in FIG. 5 in operation is generally maintained at 10−1×10¹⁰ Torr.

Alternatively, the load lock system 51 may include a heating system for preheating the substrate to an appropriate temperature. In such a case, the substrate is heated up to the appropriate temperature after loaded into the load lock system. At this time, the preheating temperature of the substrate is typically set up about 100° C. to 200° C. so that the substrate is not deformed or mechanically damaged by a heat impact when the substrate at room temperature is directly heated. The substrate loaded into the load lock system and then preheated up to the appropriate temperature is moved to the MIC source metal deposition chamber 52 by the robot arm 59. Alternatively, the robot arm may be also provided with a heating equipment for heating the substrate. A substrate holder of the MIC source metal deposition chamber 52 is always maintained at a heated state. However, since the substrate is maintained at an appropriate preheating temperature, the heat impact affecting the substrate when the substrate is loaded into the chamber 52 is very small, thereby generating no serious problem even when the substrate is loaded directly into the chamber 52. During the MIC source metal deposition, the substrate is heated up to about 200° C. or higher, preferably about 400° C. to 600° C. Therefore, during deposition of the MIC source metal such as Ni, the crystallization occurs at the portions where the source metal and the amorphous silicon make direct contact with each other. That is, during the source metal deposition, the thermal annealing for crystallization is simultaneously carried out. As for the MIC source metal deposition methods, sputtering, evaporation, e-beam evaporation, CVD may be used, and the sputtering method is most frequently used.

The substrate which has gone through the MIC source metal deposition is moved to the thermal annealing chamber 53 by the robot arm 59. In this apparatus, since the substrate is moved under vacuum and the robot arm may also be provided with a heating equipment for heating the substrate, there is no problem that the temperature of the substrate which has been taken out from the chamber 52 rapidly drops during the movement. Since the thermal annealing chambers 53 to 57 are always maintained at temperature for allowing the crystallization of amorphous silicon by MIC and MILC, i.e. preferably 400° C. to 700° C., the thermal annealing of the substrate is substantially carried out directly after the substrate is loaded into the chamber. As described above, according to the conventional process shown in FIG. 2, the vacuum state is released after the MIC source metal is deposited, and the substrate is then thermal annealed again under vacuum after removal of the photoresist. Thus, there are problems in that the process becomes complex, and that it usually takes over two hours to heat the substrate and the furnace from the preheated temperature up to the thermal annealing temperature for the crystallization. However, with the fabrication process and apparatus of the present invention, since the substrate has been already heated up to the crystallizing annealing temperature when performing the MIC source metal deposition, and moved directly into the thermal annealing chamber heated ,up to the normal thermal annealing temperature in a state where partial crystallization thereof has already started, the time required for raising the temperature of the furnace up to the thermal annealing temperature can be reduced. Thus, the productivity of the process is greatly enhanced. Further, during this thermal annealing process for the crystallization, impurities implanted into the active layer can be simultaneously activated.

Substrates are thermal annealed in a batch type within the thermal annealing chamber. That is, since each of the annealing chambers 53 to 57 includes a plurality of slots, a plurality of substrates can be simultaneously treated. The thermal annealing process is carried out under vacuum, and as the heating method, a conduction heating using a hot plate, light heating or an induction heating method may be used. Since it takes a relatively longer time to thermal anneal the substrate for crystallization compared to the MIC source metal deposition process or the wiring metal deposition process following the thermal annealing process, two or more thermal annealing chambers are typically arranged. Although five thermal annealing chambers are shown in FIG. 5, the number may be appropriately changed considering time needed for each process. Further, the temperature and heating method at each thermal annealing chamber may be varied depending on process conditions.

The substrate which has gone through the thermal annealing is moved to the wiring metal deposition chamber 58. Even during the wiring metal deposition, the substrate is maintained at the appropriate temperature. The temperature of the substrate is maintained at about 100° C. to 400° C., preferably about 150° C. to 300° C., which is lower than that needed for the crystallization thermal annealing, during the wiring metal deposition. Therefore, after the wiring metal deposition, the substrate is cooled to a temperature appropriate to exposure to room temperature. Thus, the substrate which has gone through the wiring metal deposition is taken out from the apparatus via the load lock system 51 without an additional cooling process. Alternatively, the substrate may, however, pass through a separate cooling chamber (not shown) before leaving for the load lock system, or the substrate may be cooled in the load lock system. In this case, a method of injecting inert gas such as N₂ or Ar into the chamber may be used in order to cool the substrate. Further, as for the wiring metal deposition method, sputtering, evaporation, e-beam evaporation, CVD may be used, and the sputtering method is usually used.

Thereafter, additional thermal annealing for improving the crystallization quality may be optionally carried out in the same equipment, or may be carried out after the patterning the wiring metal layer, as shown in FIG. 2.

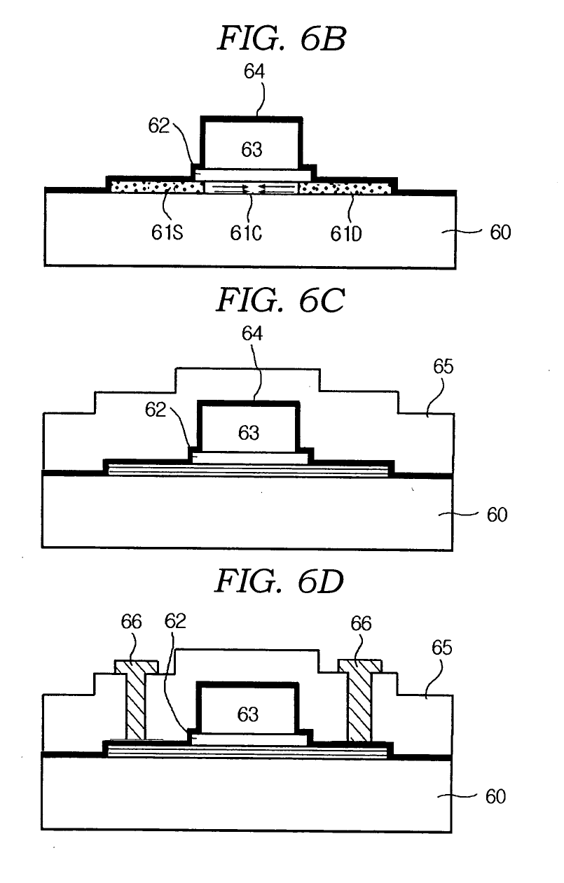

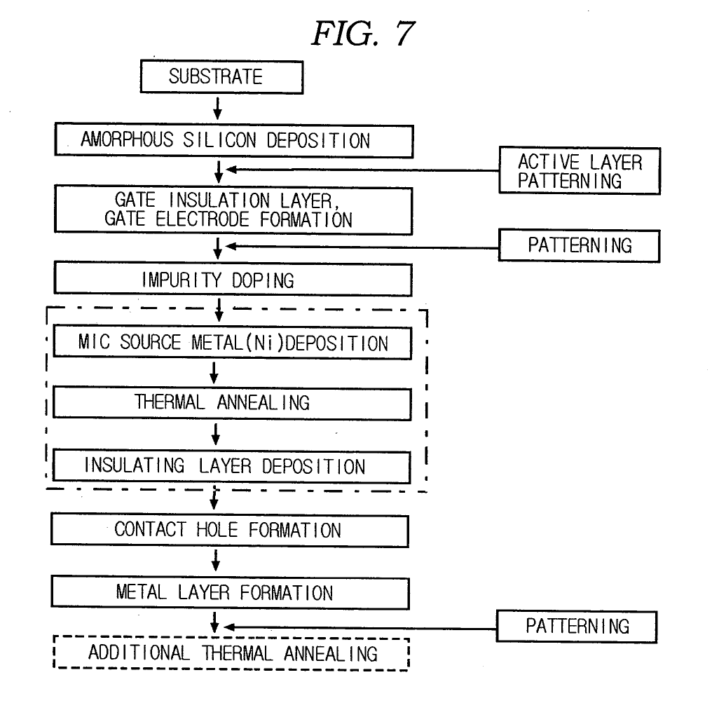

FIGS. 6A to 6D are sectional views showing the features of the method of fabricating a thin film transistor including a crystalline silicon active layer according to a second embodiment of the present invention. It should be understood that environments and conditions of each process in the embodiments according to the present invention to be described below are the same as the aforementioned process for fabricating the thin film transistor so far as it is described otherwise. In the embodiment shown in FIG. 6, the structure shown in FIG. 6A is obtained by forming a gate insulation film 62 and a gate electrode 63 on an active layer 61 formed on a substrate 60, implanting impurities (see FIG. 1C), and then depositing MIC source metal 64 thereon instead of forming an insulating layer. At this time, in order to prevent the MIC source metal 64 from deteriorating transistor characteristics due to its direct contact with a channel region, the gate insulation film 62 is formed to be wider than the gate electrode 63. Next, the crystallization of the amorphous silicon and the activation of the impurities implanted into the active layer are carried out by thermal annealing the substrate, as shown in FIG. 6B. At this time, a source region 61S and a drain region 61D coming in contact with the MIC source metal are crystallized directly by the MIC source metal, and the channel region 61C is crystallized by means of MILC propagating from the source and drain regions. An arrow in FIG. 6B indicates the propagation direction of the MILC during the thermal annealing process. After the crystallization process, an insulating layer 65 is deposited on the active layer 61 and the gate electrode 63 is formed thereon, as shown in FIG. 6c. Subsequently, the thin film transistor as shown in FIG. 6D is completed by forming contact holes on the insulating layer and then depositing and patterning wiring metal 66. These processes are summarized in a flowchart of FIG. 7.

According to the processes shown in FIG. 7, since processes of the MIC source metal deposition, the thermal annealing and the insulating layer deposition (enclosed by the dotted line) can be consecutively carried out under vacuum without an intervening photoresist forming process. Therefore, all of the above processes can be carried out within one apparatus as shown in FIG. 5. In fabricating a thin film transistor according to the processes in FIG. 7, by substituting the wiring metal layer deposition chamber 58 of the apparatus shown in FIG. 5 with a chamber for depositing an insulation film, such as silicon oxide or nitride, all of the above processes can be carried out within the single equipment. At this time, in order to deposit the insulation film, a chemical vapor deposition method such as PE-CVD, LP-CVD or AP-CVD is primarily used. However, a sputtering method, a vapor deposition method or the like may be used.

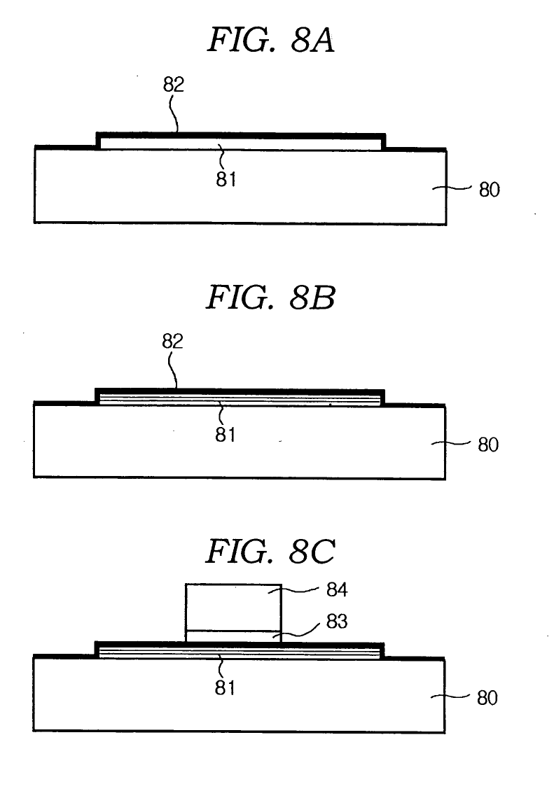

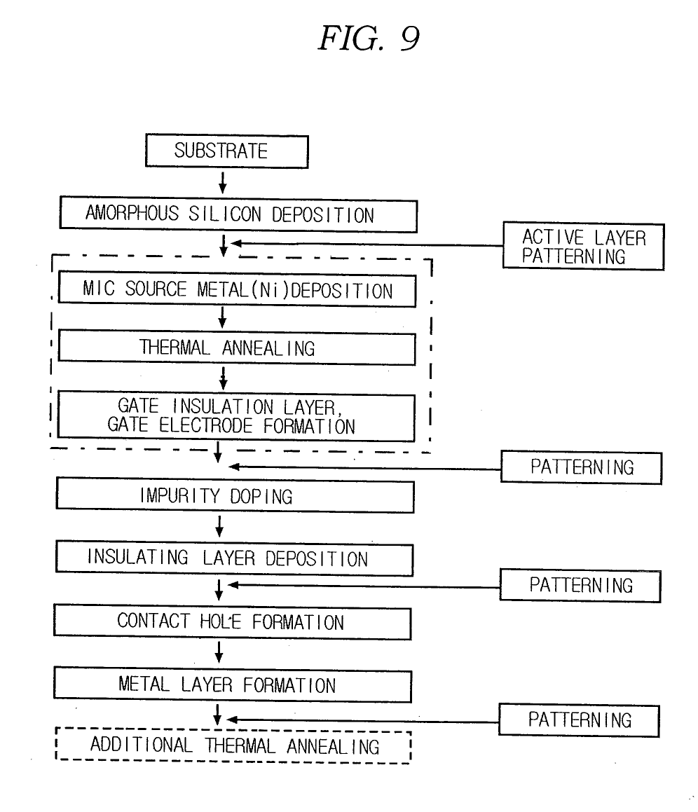

FIGS. 8A to 8C are sectional views showing features of a method of fabricating a thin film transistor including a crystalline silicon active layer according to a third embodiment of the present invention. In this embodiment, the structure shown in FIG. 8A is obtained by depositing and patterning amorphous silicon on a substrate 80 to form an active layer 81 and then depositing MIC source metal 82. Subsequently, crystallization by the MIC is induced by heating the substrate 80 and the active layer 81 (see FIG. 8B). Thereafter, the structure shown in FIG. 8C is obtained by depositing and patterning a gate insulation film 83 and a gate electrode 84 on the crystallized active layer 81. Then, the thin film transistor is completed by implanting impurities, depositing an insulating layer, and forming contact holes and contact electrodes using the gate electrode 84 as a mask. These processes are summarized in a flowchart of FIG. 9.

In this embodiment, the process of depositing the MIC source metal 82 and the thermal annealing process are carried out before formation of the gate insulation film 83. This is adopted in order to primarily prevent the gate insulation film from being damaged upon thermal annealing. According to this process sequence, the processes of MIC source metal deposition, thermal annealing and gate electrode deposition (enclosed by the dotted line) of FIG. 9 can be carried out within one equipment without releasing vacuum state. In this case, the gate electrode deposition process may be carried out within the wiring metal layer deposition chamber in the apparatus in FIG. 5. However, it is necessary to place an additional gate insulation film deposition chamber in front of the chamber. The gate insulation film deposition chamber used in this case may have the same shape and specification as the gate insulation film deposition chamber used in the second embodiment.

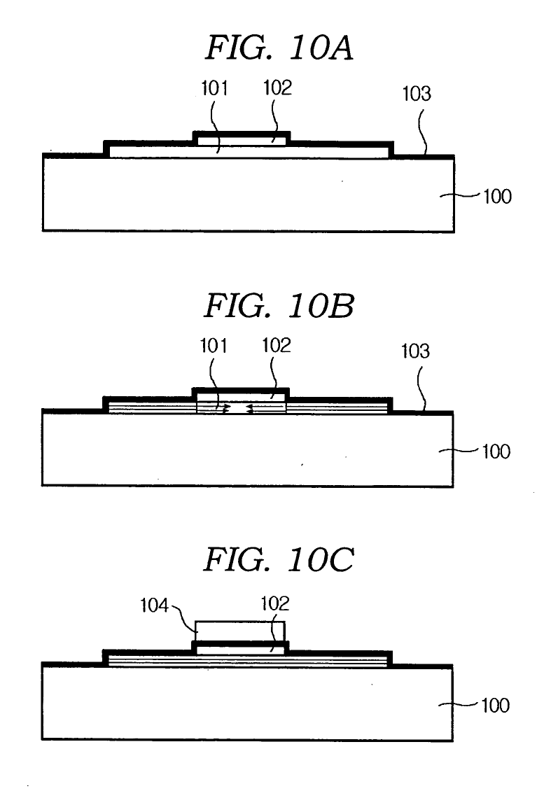

FIGS. 10A to 10C are sectional views showing features of a method of fabricating a thin film transistor including a crystalline silicon active layer according to a fourth embodiment of the present invention. In this embodiment, the structure shown in FIG. 10A is obtained by depositing and patterning a gate insulation film 102 on an active layer 101 formed on a substrate 100 and then depositing MIC source metal 103. Subsequently, the thermal annealing for crystallizing the active layer is carried out as shown in FIG. 10B. At this time, regions coming in contact with the MIC source metal (i.e. source and drain regions) are crystallized directly by the MIC source metal 103, and a region below the gate insulation film 102 are crystallized by the MILC propagating from the source and drain regions. An arrow shown in FIG. 10B indicates the propagation direction of the MILC during the thermal annealing. The structure shown in FIG. 10C is obtained by depositing and patterning a gate electrode 104 after completion of the thermal annealing. Then, the thin film transistor is completed by implanting impurities using the gate electrode as a mask and performing the subsequent processes as described with respect to the third embodiment.

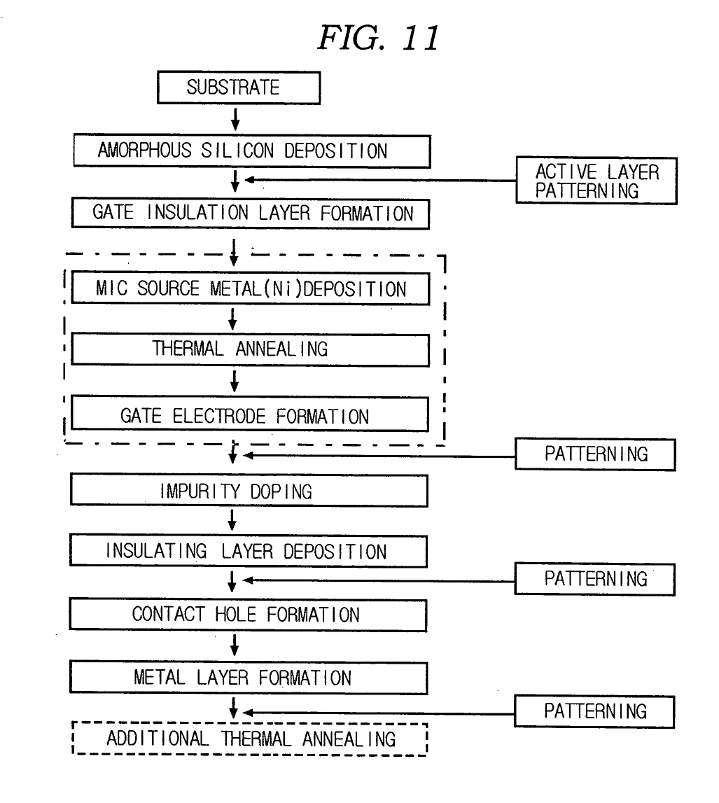

The above processes are summarized in a flowchart of FIG. 11. According to the process sequence of FIG. 11, the processes of the MIC source metal deposition, thermal annealing and gate electrode deposition (processes enclosed by the dotted line) can be carried out within one equipment. In this case, since the gate electrode deposition process is carried out within the wiring metal layer deposition chamber 58 of the apparatus shown in FIG. 5, the process of this embodiment can be carried out without changing the structure of apparatus shown in FIG. 5. As described in the above embodiments, a number of processes including the thermal annealing for the crystallization can be collectively and consecutively carried out within one equipment according to various embodiments as explained above by simply modifying the structure of the apparatus shown in FIG. 5.

According to the methods of the present invention, a group of processes, such as the processes of MIC source metal deposition, thermal annealing and wiring metal layer deposition, or the processes of MIC source metal deposition, thermal annealing and insulating layer deposition can be consecutively performed within one equipment under vacuum and maintaining the heated state of the substrate. Thus, time needed for raising the temperature of the furnace to perform the thermal annealing and lowering the temperature after completion of the thermal annealing is not required. Accordingly, time needed for the process of fabricating the thin film transistor can be greatly reduced, and the productivity thereof can be improved. In addition, according to the timing of the process of depositing the MIC source metal, the present invention may simultaneously conduct the processes of the MIC source metal deposition and the thermal annealing for crystallizing amorphous silicon and for activating impurities; the processes of thermal annealing and the deposition of wiring metal layer; or the processes of the thermal annealing and the formation of an insulating layer used for forming contact holes.

Although the present invention has been described with respect to the preferred embodiments thereof, the embodiments are only examples of the present invention and should not be construed as limiting the scope of the present invention. For example, although the above embodiments of the present invention have been described in connection with the process of fabricating the thin film transistor, the method of the present invention may be employed in fabricating the various kinds of semiconductor devices including the crystalline silicon active layer. Accordingly, it should be understood that a person having an ordinary skill in the art to which the present invention pertains can make various modifications and changes thereto without departing from the spirit and scope of the invention defined by the appended claims.

What is claimed is:

1. A method of fabricating a semiconductor device including a crystalline active layer crystallized by performing thermal annealing to an amorphous silicon layer, characterized in that:
the thermal annealing process for crystallizing the amorphous silicon layer is consecutively performed within one equipment after a process of depositing a MIC source metal onto the amorphous silicon layer and before a second material deposition process.

2. The method as claimed in claim 1, wherein the second material deposition process is a process of depositing a wiring metal layer onto the active layer.

3. The method as claimed in claim 1, wherein the second material deposition process is a process of forming an insulating layer for forming contact holes.

4. The method as claimed in claim 1, wherein the second material deposition process is a process of forming a gate insulating film and a gate electrode onto the active layer.

5. The method as claimed in claim 1, wherein the second material deposition process is a process of forming a gate electrode.

6. The method as claimed in claim 1, wherein a substrate of the semiconductor device is heated during the process of applying the MIC source metal.

7. The method as claimed in claim 6, wherein the substrate is heated to a temperature of 200° C. or higher.

8. The method as claimed in anyone of claims 1, wherein the thermal annealing process is performed under vacuum.

9. The method as claimed in claim 8, wherein the vacuum pressure during the thermal annealing process is within a range of 10 to 1.0×10⁻¹⁰ Torr.

10. The method as claimed in claim 8, wherein a temperature during the thermal annealing process is 300° C. or higher.

11. The method as claimed in anyone of claims 1 to 5, further comprising a process of implanting impurities into the active layer before the thermal annealing process of the active layer and being characterized in that the impurities are activated during the thermal annealing of the active layer.

12. The method as claimed in anyone of claims 1 to 5, further comprising an additional thermal annealing process for improving crystallization of the active layer.

13. The method as claimed in claim 2, wherein the MIC source metal is used for the wiring metal layer.

14. The method as claimed in claim 3, wherein a substrate of the semiconductor device is heated during the process of forming the insulating layer.

15. The method as claimed in claim 14, wherein the heating temperature of the substrate is lower than the thermal annealing temperature of the active layer.

16. The method as claimed in anyone of claims 1 to 5, wherein at least one material selected from a group consisting of Ni, Pd, Ti, Ag, Au, Al, Sn, Sb, Cu, Co, Cr, Mo, Tr, Ru, Rh, Cd, Pt, or a combination thereof is used as the MIC source metal.

17. The method as claimed in anyone of claims 1 to 5, wherein the semiconductor device is a thin film transistor.
